(19) United States
(12) Patent Application Publication
(10) Pub. No.: US 2013/0119908 A1
(43) Pub. Date: May 16, 2013

(54) ELECTRONIC CONTROL UNIT FOR ELECTRIC POWER STEERING

(71) Applicant: Honda Elesys Co., Ltd., Yokohama (JP)

(72) Inventors: Kazuki HARADA, Kanagawa (JP); Daiji HOTTA, Kanagawa (JP)

(73) Assignee: HONDA ELESYS CO., LTD., Yokohama (JP)

(21) Appl. No.: 13/673,120

(22) Filed: Nov. 9, 2012

(30) Foreign Application Priority Data
Nov. 10, 2011 (JP) 2011-246849

(51) Int. Cl. H02P 6/10; H05K 7/20; H05K 7/02

(52) U.S. Cl. CPC H02P 6/10; H05K 7/02; H05K 7/026; H05K 7/2039
USPC 318/400.42; 361/784; 361/803; 361/721

(57) ABSTRACT

One embodiment of the present invention provides an electronic control unit for electric power steering, including: a first board which is mounted with first surface-mount components; and only one second board which is mounted with second surface-mount components having larger allowable current capacities than the first surface-mount components, which have approximately the same components mounting area as the first board, and which is layered with the first board.

### CROSS-REFERENCE TO RELATED APPLICATION(S)

This application claims priority from Japanese Patent Application No. 2011-246849 filed on Nov. 10, 2011, the entire contents of which are incorporated herein by reference.

### FIELD

The present invention relates to an electronic control unit for electric power steering which is particularly suitable for use in vehicles which perform steering assist control using a multiphase brushless motor.

### BACKGROUND

Multiphase brushless motors are widely employed in various machines such as vehicles. For example, in recent years, electric power steering devices (PSUs) have been being developed to lower the load of vehicle driving. A PSU assist steering torque generated by a steering wheel with assist torque that is generated by a multiphase brushless motor, under the control of an electronic control unit (ECU).

An ECU typically includes a power circuit for controlling the multiphase brushless motor of a PSU and a control circuit for controlling the power circuit. Such ECU may have an insert-mold board in which DIP (dual inline package) components such as noise reduction coils, a power relay and fail-safe relays are connected by soldering, welding, or the like, to an insert mold which is mounted with bus bars by insert molding, plural aluminum power boards which are mounted with surface-mounted semiconductor switching elements for causing large currents to flow through a multiphase brushless motor, shunt resistors for current detection, etc., and a glass epoxy control board which is mounted with a control microcomputer, a drive circuit for driving the semiconductor switching elements, amplifying circuits for various external sensors, etc. The above boards are connected to each other by soldering, welding, or the like and covered with a cover. A steering wheel manipulation of a driver is assisted using torque that is generated by causing large currents to flow through the multiphase brushless motor.

To simplify the manufacturing process of the above-kind ECU and to reduce its size and thickness, only relatively tall components such as a bridge circuit consisting of pairs of semiconductor switching elements for the respective phases, smoothing electrolytic capacitors, fail-safe relays, and noise reduction coils may be mounted on a power board (refer to JP-2004-017884-A, for example). More specifically, the ECU of JP-2004-017884-A has a case which houses a control board and the power board. The case is molded integrally not only with connection lines for electrically connecting between the control board and the power board at a central region but also with a connection part for connecting two confronting side walls of the case. The case is divided into two sections by the connection part and the power board and the control board are disposed in the respective sections. In this manner, the electronic components mounted on the control board and the relatively tall electronic components mounted on the power board can be prevented from being arranged in the height direction, whereby the ECU can be made thinner.

The size of the above-kind ECU is determined depending on the sizes of the electronic components that constitute a power circuit. Since a circuit is formed using bus bars, the insert-mold board (case) is larger than the control board which includes the control unit and a part of the power circuit. Furthermore, the electronic components mounted in the above-kind ECU are a mixture of surface-mount components and DIP components, thereby increasing the number of connection steps and cost.

On the other hand, as such electronic components as an ultra-low ESR (equivalent series resistance) electrolytic capacitor have been reduced in thickness, further reduction in size of ECUs for PSUs and further flexibility of their wiring designing become desirable.

### SUMMARY

One object of the present invention is to provide an electronic control unit for electric power steering which can be made even smaller and can be increased in reliability while the flexibility of wiring designing is increased.

Claim 1 defines an electronic control unit for electric power steering, including:

a first board which is mounted with first surface-mount components; and

only one second board which is mounted with second surface-mount components having larger allowable current capacities than the first surface-mount components, which have approximately the same components mounting area as the first board, and which is layered with the first board.

Claim 2 defines, based on claim 1, the electronic control unit, further including:

a connector case which is integral with an external connector, a first rim and a second rim of the connector case being mounted with respective terminal groups by insert molding,

wherein the first board and the second board are layered via the connector case such that the terminal groups connect between the respective first surface-mount components and the respective second surface-mount components, and

wherein each of the second surface-mount components mounted on the second board is connected to a respective closer one of the terminal group mounted on the first rim and the terminal group mounted on the second rim.

Claim 3 defines, based on claim 1, the electronic control unit, further including:

a cover which sandwiches the first body with the connector case; and

a heat sink which sandwiches the second board with the connector case while cooling the second surface-mount components mounted on the second board.

Claim 4 defines, based on claim 1, the electronic control unit,

wherein the first surface-mount components include:
a control unit which performs a steering assist control using an external multiphase brushless motor by duty-ratio-driving semiconductor switching elements for supplying drive currents to respective phase windings of the multiphase brushless motor, according to steering force of a steering system detected by an external torque sensor, and

wherein the second surface-mount components include:
a multiphase bridge circuit having, for the respective phases, pairs of semiconductor switching elements which supply the drive currents determined by the duty-ratio driving to the respective phase windings of the multiphase brushless motor;
electrolytic capacitors which absorb ripples in the drive currents, at least one electrolytic capacitor being provided for each pair of semiconductor switching elements;
current detection elements which are provided on lines through which the drive currents flow, respectively, and which detects the respective phase currents;
fail-safe relays which shuts off one of the drive currents upon an abnormality at least in the one drive current; and
a power relay which is connected between a battery and the multiphase bridge circuit, and which allows or prohibits current supply to the multiphase bridge circuit.

According to claim 1, for example, a control circuit is mounted on the dedicated first board, and a power circuit is mounted on the dedicated second board. This enables to arrange the electronic components uniformly and efficiently and to thereby reduce the size of the entire electronic control unit. Since the power circuit is mounted on only one second board, the electronic control unit can be made more compact and wiring lines can be saved, that is, the wiring can be made more efficient. Since all the necessary electronic components are surface-mount components, the electronic control unit can be made thinner, and all the electronic components can be connected by reflow soldering, thereby simplifying the assembling process and lowering cost.

According to claim 2, each of the second surface-mount components can be connected to a closest one of the terminal groups which are mounted on the rims of the connector case at its signal line and thereby be connected to a first surface-mount component which is mounted on the first board. Thus, a component needs not to be wired to a distant connector due to the mounting positions of components, thereby simplifying the wiring layout and increasing the flexibility of wiring designing. Furthermore, since the flexibility of the layout of the second surface-mount components is increased and the effective components mounting area of the second surface-mount board is maximized, the size of the electronic control unit can be further reduced.

According to claim 3, the insert-molded connector case is sandwiched between the cover and the heat sink. Therefore, heat generated by a large-current-capacity second surface-mount component which is mounted on the second board is dissipated to the outside efficiently via the high-heat-dissipation-performance second board (e.g., metal board) and the heat sink. Thus, the cooling effect is enhanced, thereby enhancing reliability.

According to claim 4, the electronic control unit can be made thinner while using large-current-capacity electronic components, such as the electrolytic capacitors for smoothing and the fail-safe relays for shutting off drive current upon an abnormality. The electronic control unit can thus be made thinner. Since all the components are connected by reflow soldering, the assembling process can be simplified, thereby lowering cost.

### BRIEF DESCRIPTION OF DRAWINGS

FIG. 1 shows an appearance of an electronic control unit (ECU) for electric power steering according to an embodiment.

FIG. 2 is an exploded perspective view of the ECU.

FIG. 3 is a plan view of a control board of the ECU on which electronic components are mounted.

FIG. 4 is a plan view of a power board of the ECU on which electronic components are mounted.

FIG. 5 shows a circuit configuration of the ECU.

FIGS. 6A-6C show the entire configuration of the ECU.

FIGS. 7A and 7B and 8A to 8C show a connector case of the ECU.

FIG. 9 schematically shows a general configuration of an electric power steering device which employs the ECU according to the embodiment.

### DETAILED DESCRIPTION

An electronic control unit (ECU) 1 for electric power steering according to an embodiment will be hereinafter described in detail.

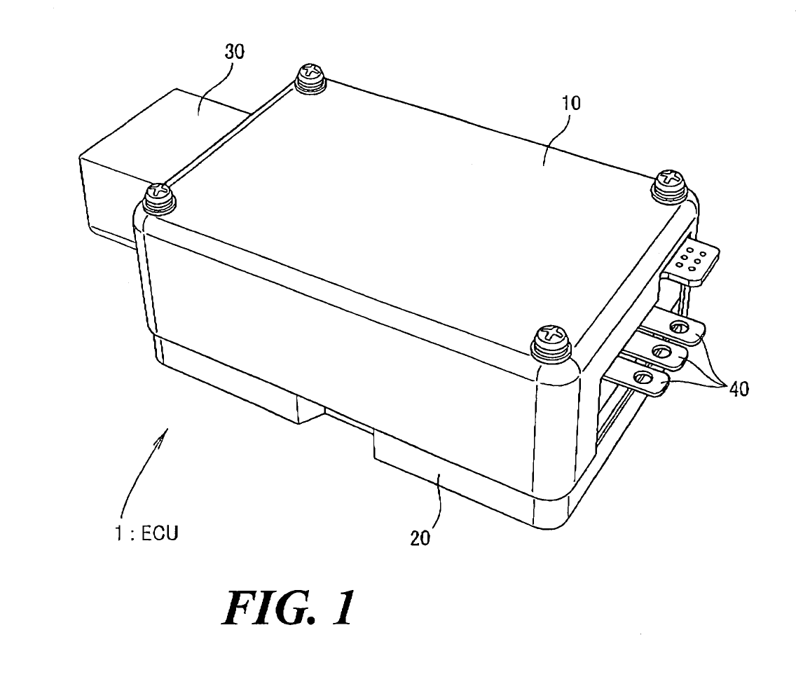

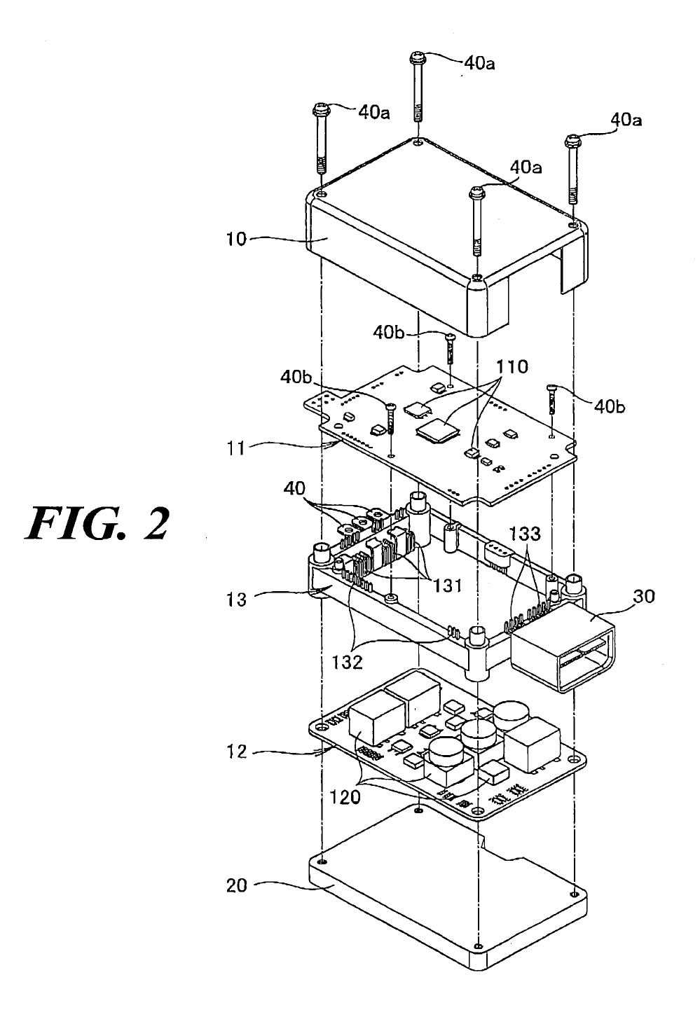

As shown in FIG. 1, the ECU 1 according to the embodiment has a layered structure in which boards (a control board 11 and a power board 12 shown in FIG. 2) mounted with electronic components are sandwiched between a cover 10 and a heat sink 20. An external connector 30 to be connected to a power system, such as an external battery 60, and other ECUs is provided at one end portion of the cover 10 in the longitudinal direction thereof. On the other hand, motor terminals 40 to be connected to an external 3-phase brushless motor are provided at the other end portion of the cover 10. Specifically, the external connector 30 and the motor terminals 40 are provided on respective end portions of a connector case 13 (see FIG. 2). For example, the cover 10 may function as an electromagnetic shield for the layered control board 11 and power board 12.

FIG. 2 is an exploded perspective view of the ECU 1 according to the embodiment. As shown in FIG. 2, the control board 11 (first board), the power board 12 (second board) and the connector case 13 are layered. The control board 11 is mounted with control surface-mount components 110 (first surface-mount components) which constitute a control circuit. The power board 12 is mounted with power surface-mount components 120 (second surface-mount components) such as a 3-phase brushless motor drive circuit which are larger in allowable current capacity than the control surface-mount components 110. The connector case 13 is disposed between the control board 11 and the power board 12 and is to be connected to external devices such as the power system and the other ECUs.

In the embodiment, all the power surface-mount components 120 are mounted on only one power board 12 which has approximately the same components mounting area as the control board 11. This structure enables uniform, efficient layout of electronic components and miniaturization of the entire ECU 1. When mounting all the power surface-mount components 120 on only one power board 12, wiring lines can be saved. When surface-mounting all of the necessary electronic components of the ECU 1, the ECU 1 can be made thin, all the electronic components can be connected by reflow soldering, and an assembling process can be simplified, thereby lowering cost.

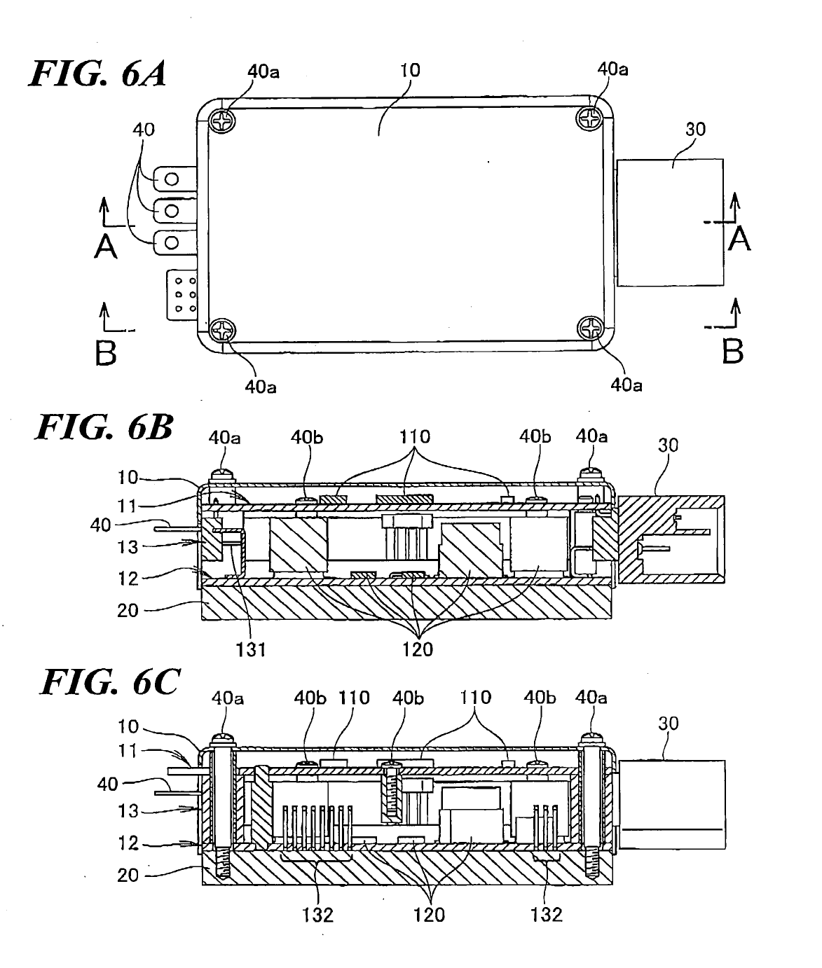

At least two rims (first rim and second rim) of the connector case 13 are mounted with terminal groups. In the embodiment, terminal groups 131, 132 and 133 are provided at the three rims of the connector case 13 by insert molding. The terminal groups 131, 132 and 133 connect between the power surface-mount components 120 and the external 3-phase brushless motor 50 (see FIG. 5), between the power surface-mount components 120 and the control surface-mount components 110, and between the power surface-mount components 120 and the external battery 60 (see FIG. 5). Each of the power surface-mount components 120 mounted on the power board 12 can be connected to a respective closest one of the terminal groups 131, 132 and 133 which are mounted on the rims of the connector case 13. The control board 11 is fixed to the connector case 13 with screws 40b at a peripheral region thereof. Then, the control board 11 and the power board 12 are sandwiched between the cover 10 and the heat sink 20, and fixed together with four screws 40a.

The term “surface-mount components” means electronic components using surface-mount technology (SMT). The surface mounting is advantageous in terms of mounting space, as it requires only a small mounting space while, for example, the through-hole mounting requires fixing of the leads of electronic components to holes of a printed circuit board. For example, in the surface mounting, first, a solder pattern is printed on a board by a cream solder printer or adhesive is applied to component mounting portions by a dispenser, then, components are mounted by a chip mounter, and then, the solder is melted by applying heat in a solder reflow furnace. Thus, the electronic components are fixed to the board upon solidification of the solder. The term “allowable current capacity” means a rated maximum current that is allowed to flow through an electronic component. When a voltage is applied, an electronic component heats up due to a current flowing therethrough according to its electric resistance. If an insulating coating of the electronic component is melted because of its heating, the electronic component is short-circuited, or even ignites, for example. An allowable current capacity is set for each kind of electronic component to prevent such occasions.

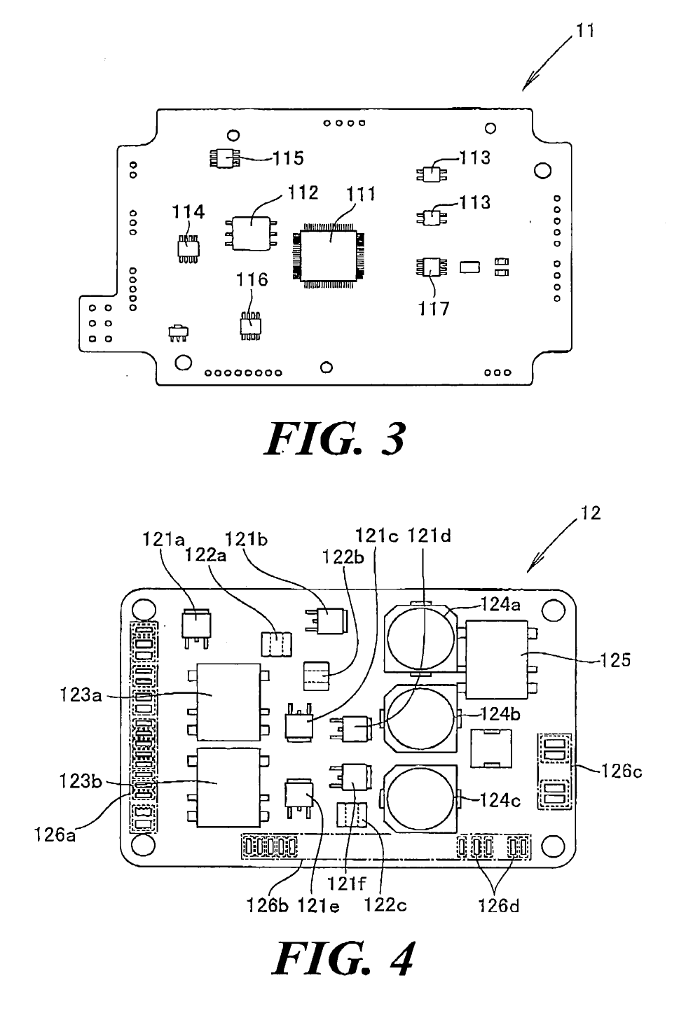

FIG. 3 shows the control surface-mount components 110 which are mounted on the control board 11. The control surface-mount components 110 include a control unit (CPU) 111 which acquires a steering torque signal from a torque sensor 70 (see FIG. 5) and a vehicle speed signal from a vehicle speed sensor 80 (see FIG. 5), calculates an assist torque and a drive direction according to these signals, and drive-controls the 3-phase brushless motor 50 while receiving signals indicating currents flowing through the 3-phase brushless motor 50 and a feedback signal supplied from an amplifier 116 for the angular sensor 90. The control surface-mount components 110 also include a drive circuit 112 for driving semiconductor switching elements 121a-121f of a 3-phase bridge circuit 121 (see FIG. 5), a relay drive circuit 113 for driving a power relay 125 (see FIG. 5), and a phase current detection circuit 114 (see FIG. 5) including signal amplifiers 114a-114c for detecting phase currents through shunt resistors 122a-122c (see FIG. 5) which are provided for the respective phases. The drive circuit 112 and the relay drive circuit 113 operate under the control of the control unit 111. The control surface-mount components 110 further include a torque sensor circuit including a power source 115 for the external torque sensor 70, an angular sensor circuit including the amplifier 116 for the external angular sensor 90, and a CAN (control area network) communication LSI 117 for communicating with the other ECUs.

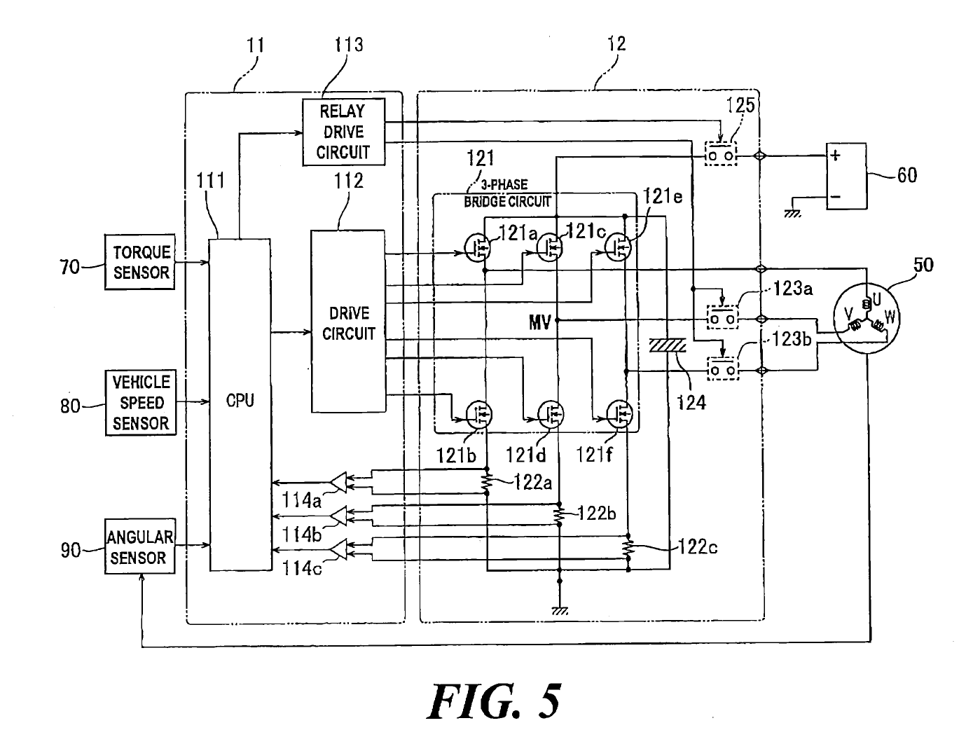

FIG. 4 shows the power surface-mount components 120 which are mounted on the power board 12. In this example, the power surface-mount components 120 include the semiconductor switching elements 121a-121f of the 3-phase bridge circuit 121, the phase current detection shunt resistors 122a-122c which are provided for the respective phases of the 3-phase brushless motor 50, fail-safe relays 123a and 123b, smoothing electrolytic capacitors 124a-124c, and the power relay 125. Peripheral terminal groups 126a-126c are provided at a peripheral regions of the power board 12. A part of the power surface-mount components 120 are connected to the 3-phase lines of the external 3-phase brushless motor 50 via part of the terminal group 126a and the part of the terminal group 131 which is mounted on the connector case 13. The other part of the power surface-mount components 120 are connected to the control board 11 via the other part of the peripheral terminal group 126a, the peripheral terminal group 126b, and a part of the peripheral terminal group 126c, or are connected to a battery (not shown) via the other part of the peripheral terminal group 126c.

FIG. 5 shows a circuit configuration of the ECU 1 according to the embodiment. As shown in FIG. 5, the ECU 1 includes the control board 11 which is mounted with the control unit (CPU) 111, the drive circuit 112, the relay drive circuit 113, and the signal amplifiers 114a-114c of the phase current detection circuit 114. The ECU 1 also includes the power board 12 which is mounted with the 3-phase bridge circuit 121, the 3-phase bridge circuit 121, the shunt resistors 122a-122c, the fail-safe relays 123a and 123b, the three electrolytic capacitors 124, and the power relay 125. The torque sensor 70, the vehicle speed sensor 80 and the angular sensor 90 are connected to the control unit 111. The 3-phase brushless motor 50 is connected to the 3-phase bridge circuit 121 via the fail-safe relays 123a and 123b.

The 3-phase bridge circuit 121 includes six switching elements TUU (121a), TUL (121b), TVU (121c), TVL (121d), TWU (121e) and TWL (1210 which are MOS-FETs (metal oxide semiconductor-field effect transistors) or IGBTs (insulated gate bipolar transistors), for example.

The U-phase upper switching element TUU (121a) and the U-phase lower switching element TUL (121b) are connected to each other in series. The V-phase upper switching element TVU (121c) and the V-phase lower switching element TVL (121d) are connected to each other in series. And, the W-phase upper switching element TWU (121e) and the W-phase lower switching element TWL (1210 are connected to each other in series. The upper switching elements TUU (121a), TVU (121c) and TWU (121e) of the respective phases are connected to the positive terminal of the battery 60. That is, the series circuit of the U-phase switching elements TUU (121a) and TUL (121b), the series circuit of the V-phase switching elements TVU (121c) and TVL (121d), and the series circuit of the W-phase switching elements TWU (121e) and TWL (121f) are connected to each other in parallel.

The phase current detection circuit 114 includes shunt resistors RSU (122a), RSV (122b) and RSW (122c), and the signal amplifiers 114a-114c. The U-phase lower switching element TUL (121b), the V-phase lower switching element TVL (121d) and the W-phase lower switching element TWL (121f) are grounded via the shunt resistors RSU (122a), RSV (122b) and RSW (122c), respectively. The phase current detection circuit 114 detects phase currents flowing through the respective phases U, V and W lines of the 3-phase brushless motor 50 using the respective shunt resistors RSU (122a), RSV (122b) and RSW (122c), and outputs signals indicating the detected phase currents to the control unit 111. That is, the phase current detection circuit 114 detects phase currents flowing through the respective phases U, V and W lines individually.

The fail-safe relays 123 are the V-phase relay 123a and the W-phase relay 123b. The connecting point MV of the V-phase upper switching element TVU (121c) and the V-phase lower switching element TVL (121d) is connected to the V-phase winding of the 3-phase brushless motor 50 via the V-phase relay 123a. The connecting point of the W-phase upper switching element TVW (121e) and the W-phase lower switching element TVW (121f) is connected to the W-phase winding of the 3-phase brushless motor 50 via the W-phase relay 123b. Although three fail-safe relays may be provided for the respective phases, the necessary function can be attained as long as at least two fail-safe relays are provided. The U-, V- and W-phase windings of the 3-phase brushless motor 50 are connected to the switching elements TUU (121a) and TUL (121b), the switching elements TVU (121c) and TVL (121d), and the switching elements TWU (121e) and TWL (121f) by the phase lines, respectively.

The electrolytic capacitors 124 are connected in parallel to each of the series circuits of the U-, V- and W-phase upper and lower semiconductor switching elements, for smoothing. The power relay 125 is connected between the battery 60 and the 3-phase bridge circuit 121, and allows or prohibits current supply to the 3-phase bridge circuit 121 under the control of control unit 111 via the relay drive circuit 113.

The control unit (CPU) 111 operates according to, for example, a program, and controls the drive circuit 112 and the relay drive circuit 113. The control unit 111 generates a PWM (pulse width modulation) control signal according to signals received from the torque sensor 70 and the angular sensor 80, and controls the drive circuit 112 using the PWM control signal. The drive circuit 112 on/off-drives the switching elements TUU (121a), TUL (121b), TVU (121c), TVL (121d), TWU (121e) and TWL (121f) with a proper duty ratio. As a result, the 3-phase brushless motor 50 receives resulting currents and generates assist torque. The relay drive circuit 113 on/off-drives the fail-safe relays 123a and 123b and the power relay 125.

A target current map is stored in a memory (not shown). The control unit 111 calculates an optimum target value for assisting the steering force of the steering wheel based on a vehicle speed detection value detected by the vehicle speed sensor 80, a rotation angle value detected by the angular sensor 90, and phase current detection values detected by the phase current detection circuit 114, by referring to the target current map. The control unit 111 drive-controls the switching elements TUU (121a), TUL (121b), TVU (121c), TVL (121d), TWU (121e) and TWL (121f) by determining a current instruction value based on the calculated target value, generating the PWM signal to have a duty ratio corresponding to the current instruction value, and outputting the generated PWM signal to the drive circuit 112.

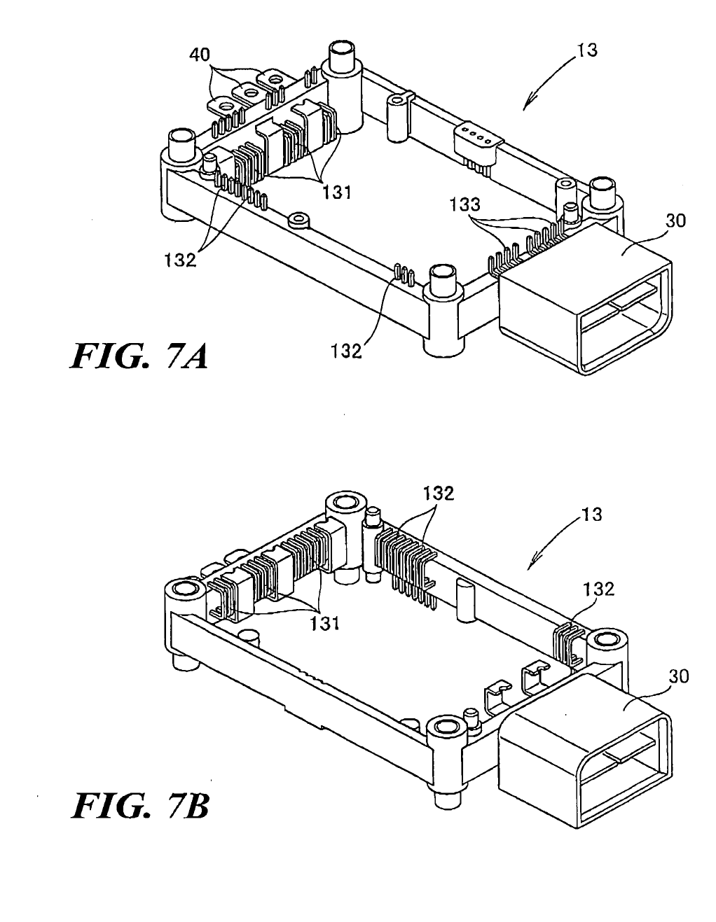

FIGS. 6A-6C show the entire configuration of the ECU 1 according to the embodiment. FIG. 6A is a plan view, FIG. 6B is a sectional view taken along line A-A in FIG. 6A, and FIG. 6C is a sectional view taken along line B-B in FIG. 6A. As shown in FIG. 6A, the external connector 30 and the motor terminals 40 project from end portions of the cover 10 in the longitudinal direction thereof, and corner portions of the cover 10 are fixed to the heat sink 20 with the screws 40a. Specifically, the external connector 30 and the motor terminals 40 are provided at the end portions of the connector case 13.

As shown in FIGS. 6B and 6C, the control board 11 (see FIG. 3) and the power board 12 (see FIG. 4) are sandwiched between the cover 10 and the heat sink 20. The control board 11 is fixed to the connector case 13 at three points, and the rod-like terminal group 131 which projects from the connector case 13 is connected to the peripheral terminal group 126a of the power board 12. The components shown in FIGS. 6A-6C that are given the same reference symbols as components shown in FIG. 1 or 2 are the same as the latter.

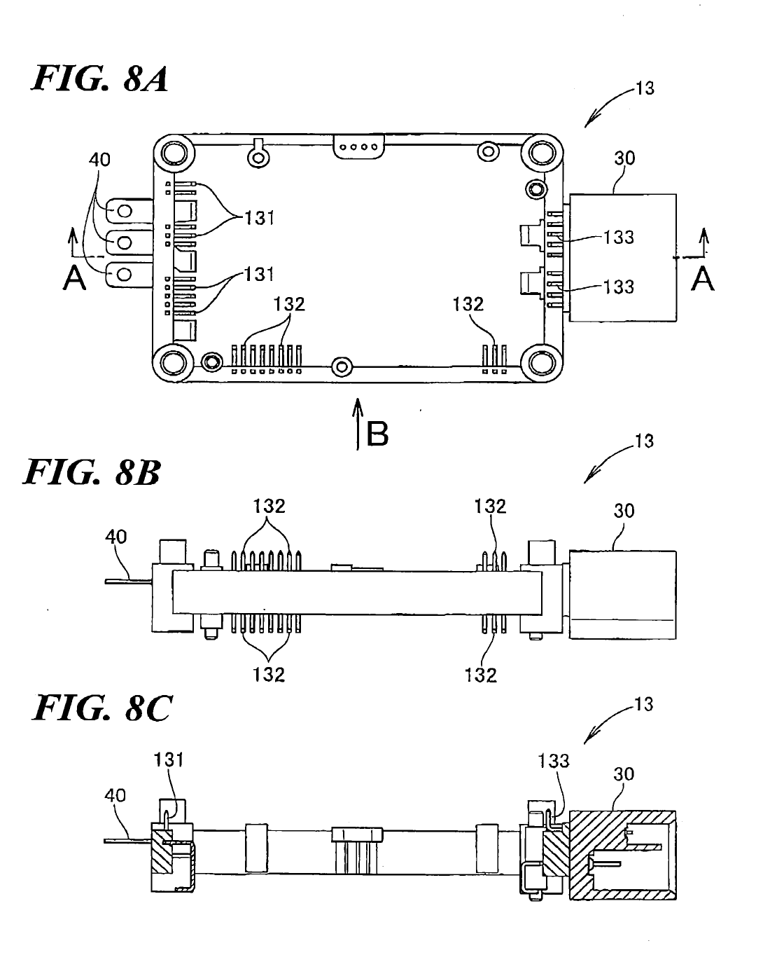

FIGS. 7A and 7B and 8A to 8C show the connector case 13 shown in FIGS. 6A-6C. FIG. 7A shows an appearance of the connector case 13 obliquely from above, and FIG. 7B shows an appearance of the connector case 13 obliquely from below. FIG. 8A is a plan view, FIG. 8B is a side view from the direction of arrow B in FIG. 8A, and FIG. 8C is a sectional view taken along line A-A in FIG. 8A. The components shown in FIGS. 7A and 7B and FIGS. 8A-8C that are given the same reference symbols as components shown in FIGS. 6A-6C are the same as the latter.

The connector case 13 is sandwiched between the cover 10 which covers the control board 11 and the power board 12 and the heat sink 20 for cooling the power surface-mount components 120 which are mounted on the power board 12. The rims of the connector case 13 are mounted with the terminal groups 131, 132 and 133 by insert molding. As described above, the terminal groups 131, 132 and 133 connect between the control surface-mount components 110, the power surface-mount components 120, the external 3-phase brushless motor 50 and the external battery 60. Each of the power surface-mount components 120 mounted on the power board 12 is connected to a respective closest one of the terminal groups 131, 132 and 133.

The power surface-mount components 120 include the 3-phase bridge circuit 121 having, for the respective phases, the pairs of semiconductor switching elements which supply phase currents for duty-ratio driving to the respective phase windings of the 3-phase brushless motor 50, the electrolytic capacitors 124 which absorb ripples in the phase currents (at least one electrolytic capacitor 124 is provided for each pair of semiconductor switching elements), the shunt resistors 122a-122c which are provided on the phase lines to detect the respective phase currents, and the fail-safe relays 123a and 123b which shut off that phase current upon an abnormality in a phase current flowing through one winding of the 3-phase brushless motor 50.

Since the power surface-mount components 120 are mounted on the single power board 12, the ECU 1 can be made compact, and all the components 120 can be connected by reflow soldering together with the control surface-mount components 110 of the control board 11.

The external connector 30 and the motor terminals 40 are mounted on the connector case 13 by insert molding. And, the rims of the connector case 13 are mounted with the terminal groups 131, 132 and 133 by insert molding. The terminal group 133 corresponding to the external connector 30 connects not only between the control surface-mount components 110 and the power surface-mount components 120 within the ECU 1, but also between the ECU 1 and the external devices including the battery 60. Further, the terminal group 131 corresponding to the motor terminals 40 connects not only between the control surface-mount components 110 and the power surface-mount components 120 within the ECU 1, but also between the ECU 1 and the 3-phase brushless motor 50, the torque sensor 70, the vehicle speed sensor 80 and the angular sensor 90.

Since the control board 11 and the power board 12 are mounted with the respective components independently of each other, the components can be arranged uniformly and efficiently, and the ECU 1 can thereby be made smaller. Since only one power board 12 is used, wiring lines for connecting between the components can be saved. The cooling effect is enhanced by mounting the power surface-mount components 120 on a metal power board 12 which exhibits high heat dissipation performance, and bringing it into direct contact with the heat sink 20. Since the control board 11 and the power board 12 are sandwiched between the cover 10 and the heat sink 20, the ECU 1 can be made smaller and thinner. Since all the components are surface-mount components, all the components can be mounted by reflow soldering, and the ECU manufacturing process is simplified, thereby lowering cost.

Since each of the signal exchange terminal groups 131, 132 and 133 is linearly arranged in the corresponding rim of the connector case 13, each of the power surface-mount components 120 mounted on the power board 12 can be connected to a closest one of the terminal groups 131, 132 and 133, thereby saving wiring lines, increasing the flexibility of components layout, and maximizing the effective components mounting area. This contributes to size reduction of the ECU 1.

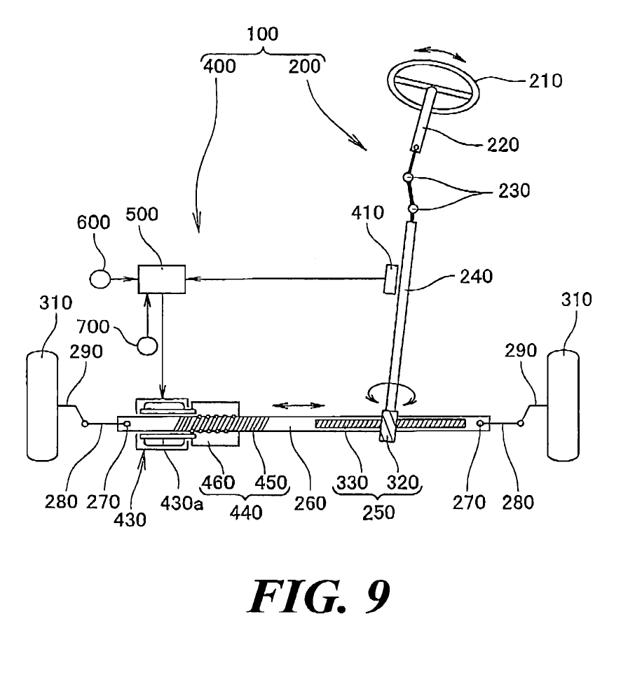

The above-described ECU 1 is mounted on a PSU 100 as a control device. FIG. 9 schematically shows a general configuration of the PSU 100. The PSU 100 includes a steering system 200 (from a vehicle steering wheel 210 to drive wheels (e.g., front wheels) 310 and an assist torque mechanism 400 for transmitting assist torque to the steering system 200.

The steering system 200 includes the steering wheel 210, a pinion shaft 240 which is connected to the steering wheel 210 via a steering shaft 220 and universal couplings 230, a rack shaft 260 which is connected to the pinion shaft 240 via a rack and pinion mechanism 250, and the left and right drive wheels 310 which are connected to the two ends of the rack shaft 260 via ball joints 270, tie rods 280, and knuckles 290, respectively. The rack and pinion mechanism 250 consists of a pinion 320 which is formed on the pinion shaft 240 and a rack 330 which is formed on the rack shaft 260. The steering system 200 allows the driver to steer the left and right drive wheels 310 via the rack and pinion mechanism 250, the rack shaft 260, and the left and right tie rods 280 through steering torque that is generated when the driver manipulates the steering wheel 210.

The assist torque mechanism 400 includes a torque sensor 410, a 3-phase brushless motor 430, a torque transmission mechanism 440, the ECU 1 as a brushless motor control device 500, a vehicle speed sensor 600, and an angular sensor 700. The torque sensor 410 detects steering torque, applied to the steering wheel 210, of the steering system 200. The vehicle speed sensor 600 detects a vehicle speed. The angular sensor 700 detects a rotation angle of the 3-phase brushless motor 430. The torque transmission mechanism 440 is a ball screw mechanism, for example.

In the thus-configured assist torque mechanism 400, the ECU 1 generates a control signal based on steering torque detected by the torque sensor 410, the 3-phase brushless motor 430 generates assist torque (motor torque) corresponding to the detected steering torque based on the control signal, and the torque transmission mechanism 440 transmits the generated assist torque to the rack shaft 260. More specifically, the ECU 1 generates a control signal based not only on the steering torque, but also on a vehicle speed detected by the vehicle speed sensor 600 and a rotation angle of the 3-phase brushless motor 430 detected by the angular sensor 700.

A motor shaft 430a of the 3-phase brushless motor 430 is a hollow shaft which covers the rack shaft 260. The torque transmission mechanism (ball screw mechanism) 440 includes a screw portion 450 which is formed on the rack shaft 260 in a region where the rack 330 is formed, a nut 460 which is engaged with the screw portion 450, and a large number of balls. The nut 460 is connected to the motor shaft 430a. Alternatively, the torque transmission mechanism 440 may be configured so as to transmit assist torque generated by the 3-phase brushless motor 430 directly to the pinion shaft 240.

The PSU 100 which employs the ECU 1 according to the embodiment allows a driver to steer the drive wheels 310 using what is called composite torque which is steering torque transmitted from the steering wheel 210 to the rack shaft 260 plus assist torque generated by the 3-phase brushless motor 430.

### Advantages of the Embodiment

In the ECU 1 according to the embodiment, the control circuit, for example, is mounted on the dedicated control board 11 (first board) and the power circuit, for example, is mounted on the dedicated power board 12 (second board). Thus, the electronic components can be arranged uniformly and efficiently, thereby reducing the size of the entire ECU 1. Since the power circuit is mounted on only one second board, wiring lines can be saved, that is, the wiring can be made more efficient. Since all the necessary electronic components are surface-mount components, the ECU 1 can be made thinner, and all the electronic components can be connected by reflow soldering, thereby simplifying the assembling process and lowering cost.

In the ECU 1 according to the embodiment, each of the power surface-mount components 120 (second surface-mount components) can be connected to a closest one of the terminal groups which are mounted on the rims of the connector case 13 at its signal line, and thereby be connected to a control surface-mount component 110 (first surface-mount component) which is mounted on the first board. Thus, a component needs not to be wired to a distant connector due to the mounting positions of components, thereby simplifying the wiring layout and increasing the flexibility of wiring designing. Furthermore, since the flexibility of the layout of the second surface-mount components is increased and the effective components mounting area of the second surface-mount board is maximized, the size of the ECU 1 can be further reduced.

In the ECU 1 according to the embodiment, the insert-molded connector case 13 is sandwiched between the cover 10 and the heat sink 20. Therefore, heat generated by a large-current-capacity second surface-mount component which is mounted on the second board is dissipated to the outside efficiently via the high-heat-dissipation-performance second board (e.g., metal board) and the heat sink 20. Thus, the cooling effect is enhanced, thereby enhancing reliability. Further, the ECU 1 can be made thinner while using large-current-capacity electronic components, such as the electrolytic capacitors 124 for smoothing and the fail-safe relays 123a and 123b for shutting off phase current upon an abnormality. Since all the components are connected by reflow soldering, the assembling process can be simplified, thereby lowering cost.

1. An electronic control unit for electric power steering, including:
a first board which is mounted with first surface-mount components; and
only one second board which is mounted with second surface-mount components having larger allowable current capacities than the first surface-mount components, which have approximately the same components mounting area as the first board, and which is layered with the first board.

2. The electronic control unit of claim 1, further including:
a connector case which is integral with an external connector, a first rim and a second rim of the connector case being mounted with respective terminal groups by insert molding,
wherein the first board and the second board are layered via the connector case such that the terminal groups connect between the respective first surface-mount components and the respective second surface-mount components, and
wherein each of the second surface-mount components mounted on the second board is connected to a respective closer one of the terminal group mounted on the first rim and the terminal group mounted on the second rim.

3. The electronic control unit of claim 1, further including:
a cover which sandwiches the first body with the connector case; and
a heat sink which sandwiches the second board with the connector case while cooling the second surface-mount components mounted on the second board.

4. The electronic control unit of claim 1,
wherein the first surface-mount components include:
a control unit which performs a steering assist control using an external multiphase brushless motor by duty-ratio-driving semiconductor switching elements for supplying drive currents to respective phase windings of the multiphase brushless motor, according to steering force of a steering system detected by an external torque sensor, and
wherein the second surface-mount components include:
a multiphase bridge circuit having, for the respective phases, pairs of semiconductor switching elements which supply the drive currents determined by the duty-ratio driving to the respective phase windings of the multiphase brushless motor;
electrolytic capacitors which absorb ripples in the drive currents, at least one electrolytic capacitor being provided for each pair of semiconductor switching elements;
current detection elements which are provided on lines through which the drive currents flow, respectively, and which detects the respective phase currents;
fail-safe relays which shuts off one of the drive currents upon an abnormality at least in the one drive current; and
a power relay which is connected between a battery and the multiphase bridge circuit, and which allows or prohibits current supply to the multiphase bridge circuit.
